(19) United States
(12) Patent Application Publication
(10) Pub. No.: US 2007/0227661 A1
(43) Pub. Date: Oct. 4, 2007

(54) MICROWAVE PLASMA PROCESSING APPARATUS, METHOD FOR MANUFACTURING MICROWAVE PLASMA PROCESSING APPARATUS AND PLASMA PROCESSING METHOD

(75) Inventor: Takahiro HORIGUCHI, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/694,011

(22) Filed: Mar. 30, 2007

(30) Foreign Application Priority Data
Mar. 30, 2006 (JP) 2006-095900

(51) Int. Cl. B44C 1/22; C23F 1/00; C23C 16/00

(52) U.S. Cl. 156/345.41; 118/723 MW; 216/69

(57) ABSTRACT

A microwave plasma processing apparatus 100 includes a processing chamber U, a plurality of dielectric parts 31 that allow microwaves to be transmitted into the processing chamber U, a beam 27 that supports the dielectric parts 31 and a fixing means for fixing the beam 27 to a processing container from outside the processing chamber U. The fixing means includes a plurality of screws 56 that are inserted at a plurality of through holes 21b present at the processing chamber U from the outside of the processing chamber U to interlock with the beam 27. Since the beam 27 is fixed to the processing chamber U via the plurality of screws 56 from the outside of the processing chamber U, better smoothness and flatness is achieved at the surface S of the beam 27 which comes in contact with plasma.

### CROSS REFERENCE TO RELATED APPLICATION

The present invention contains subject matter related to Japanese Patent Application JP 2006-095900 filed in the Japan Patent Office on Mar. 30, 2006, the entire contents of which are incorporated herein by reference.

### BACKGROUND OF THE INVENTION

1. Field of the Invention

The present invention relates to a plasma processing apparatus that processes a subject to be processed with plasma generated by raising a gas to plasma with the power of microwaves, a method for manufacturing the microwave plasma processing apparatus and a plasma processing method. More specifically, it relates to a method that may be adopted when fixing beams that support a dielectric member.

2. Description of the Related Art

Numerous types of plasma processing apparatuses have been developed to date to be adopted in plasma processing executed on a subject to be processed such as a substrate with plasma generated by raising a gas supplied into a processing chamber. Such plasma processing apparatuses include microwave plasma processing apparatuses that generate plasma by inducing electrolytic dissociation and direct dissociation of the gas with the power of microwaves and execute processing such as CVD (chemical vapor deposition) processing or etching on the substrate with the plasma thus generated.

### SUMMARY OF THE INVENTION

The microwaves, having been propagated through a waveguide and having passed through slots at a slot antenna, are then transmitted through the dielectric member and are supplied into the processing chamber. The electrical field energy of the supplied microwaves concentrates at pointed areas. In addition, the plasma generated with the electrical field energy of the microwaves readily enters a narrow space and induces an abnormal discharge therein. The concentration of the electrical field energy and the abnormal discharge that occur as described above induce excessive dissociation of the gas, as a result, leads to inconsistencies and instability in the plasma. The substrate cannot be processed in a desirable manner with such inconsistent and unstable plasma. Accordingly, uniform plasma should be generated in a stable manner by minimizing the presence of recesses and projections at surfaces that come in contact with the plasma in the processing chamber.

For instance, in a plasma processing apparatus adopting a structure in which the upper surface of the dielectric member with its peripheral edge supported with beams and the ceiling surface (the lower surface of the top plate) of the processing chamber are set in surface contact with each other, screws are threaded from the inside of the processing chamber into through holes formed at the beams and the beams and the top plate are fixed to each other (i.e., the dielectric member is fixed onto the ceiling surface of the processing chamber) by interlocking the screws with threaded openings in the top plate, the head portions of the screws are exposed at the surface inside the processing chamber with which the plasma comes into contact. This results in concentration of the electrical field energy at projected portions or recessed portions of the exposed screw heads or at the edges of the screw contact portions. As a result, an abnormal discharge caused by plasma having entered at the recessed portions of the screw heads or gaps created between the screws and the screw holes. Excessive dissociation of the gas thus occurs, leading to inconsistency and instability of the plasma. As a result, the substrate cannot be processed with plasma in desirable condition.

In order to address the issues discussed above, the present invention provides a microwave plasma processing apparatus with a surface inside the processing chamber, which comes in contact with the plasma, smoothed and flattened so as not to allow electrical field concentration to occur readily, a method for manufacturing the microwave plasma processing apparatus and a plasma processing method.

Namely, the issues are addressed in an embodiment of the present invention by providing microwave plasma processing apparatus that processes a subject with plasma generated by raising a gas to plasma with microwaves, including, a processing chamber, a dielectric member that allows the microwaves to be transmitted into the processing chamber, a beam that supports the dielectric member; and a fixing means for fixing the beam to the processing chamber from outside the processing chamber.

The fixing means may fix the beam onto the processing chamber from the outside of the processing chamber by inserting a plurality of screws from the outside of the processing chamber into a plurality of through holes present at the processing chamber and interlocking the screws inserted into threaded openings disposed at the beam.

As explained earlier, the electrical field energy of microwaves tends to concentrate at points. In addition, plasma generated with the electrical field energy of the microwaves tends to readily enter narrow spaces. This means that the presence of recesses and projections within the processing chamber must be minimized.

In the embodiment of the present invention, the beam may be fixed onto the processing chamber from the outside of the processing chamber, for instance, by screwing the beam onto a top plate from the outside of the processing chamber. In this structure, no screws are exposed over the surfaces that come in contact with the plasma inside the processing chamber. In other words, the surfaces that come in contact with the plasma inside the processing chamber are smoothed and flattened. Since the presence of recesses and projections at the surfaces that come in contact with the plasma inside the processing chamber is substantially eliminated, concentration of electrical field energy around projected portions or entry of plasma at recessed portions which would induce an abnormal discharge can be inhibited. The structure thus makes it possible to generate uniform plasma in a stable manner without inducing excessive dissociation of the gas. As a result, the substrate can be processed with plasma in desirable condition.

It is desirable that the plurality of screws be set over intervals equal to or less than λ g/4, with λ g representing the wavelength of the microwaves traveling through the waveguide. Generally speaking, waves with a wavelength λ cannot advance through gaps formed with an interval equal to or less than λ/4. By setting the plurality of screws over intervals equal to or less than λ g/4, it is ensured that microwaves having been propagated through the waveguide and having been transmitted through the dielectric member do not leak through the gaps between the through holes at which the screws are inserted and the screws themselves, to result in a loss of microwave power.

In addition, an O-ring may be disposed so as to seal the gap between each of the through holes at which the screws are inserted and the corresponding screw. In this case, the O-ring separates the space inside the processing chamber from the outside. As a result, after depressurizing the processing chamber to a specific level of vacuum, desirable plasma processing can be executed on the subject to be processed in the processing chamber sustained in an airtight condition.

The beam may be constituted of a nonmagnetic, electrically conductive material. Also, the screws may be constituted of a nonmagnetic, electrically conductive material. By assuring a high level of electrical conductivity at these members, magnetization of the members attributable to the electromagnetic field energy in the microwaves can be inhibited. Consequently, since no magnetism is imparted from the beam or the screws to affect the plasma, uniform plasma can be generated.

The dielectric member may be constituted with a plurality of dielectric parts and the beam may be formed in a lattice structure so as to support the plurality of dielectric parts. In such a case, the plurality of screws must be set at the ceiling surface in a pattern corresponding to the shape of the lattice beam in order to fix the beams onto the ceiling surface. Since the beams are screwed on from the outside of the processing chamber, no screws are exposed at the ceiling surface in the microwave plasma processing apparatus adopting the structure. Thus, since no concentration of the electrical field energy in the space under the dielectric member, abnormal discharge does not occur in the space, excessive dissociation of the gas does not occur and uniform plasma can be generated in a stable manner.

It is to be noted that the dimensions of the processing chamber should be equal to or greater than 720 mm×720 mm. In addition, the power of the microwaves supplied from a microwave generator into the processing chamber may be within a range of 1˜8 W/cm², it is desirable to set the microwave power within a range of 2.2˜3 W/cm².

The issues discussed earlier are also addressed in another embodiment of the present invention by providing a method for manufacturing a microwave plasma processing apparatus that includes a processing chamber, a dielectric member that allows microwaves to be transmitted into the processing chamber and a beam that supports the dielectric member, and processes a subject with plasma generated by raising to plasma a gas with the microwaves transmitted through the dielectic member. The dielectric member is supported at the beam and the beam is fixed onto the processing chamber by inserting a plurality of screws from the outside of the processing chamber through a plurality of through holes present at the processing chamber and interlocking the screws with the beam.

The beam is fixed onto the processing chamber from the outside of the processing chamber. In other words, the beam is screwed onto a top plate from the outside of the processing chamber. This means that no screws are exposed at surfaces that come in contact with the plasma inside the processing chamber. A microwave plasma processing apparatus with smoothed and flattened surfaces that come in contact with the plasma inside the processing chamber, substantially devoid of recesses or projections, is thus manufactured. Consequently, concentration of electrical field energy around projected portions or entry of plasma at recessed portions which would induce an abnormal discharge can be inhibited. The structure thus makes it possible to generate uniform plasma in a stable manner without inducing excessive dissociation of the gas. As a result, the substrate can be processed with plasma in a desirable condition.

It is desirable that the plurality of screws be inserted through the plurality of through holes formed at the processing chamber with intervals equal to or less than λ g/4 and thus the plurality of screws, too, be set with intervals equal to or less than λ g/4.

The issues discussed earlier are also addressed in yet another embodiment of the present invention by providing a plasma processing method for plasma-processing a subject to be processed, to be adopted in conjunction with a microwave plasma processing apparatus including a processing chamber, a dielectric member that allows microwaves to be transmitted into the processing chamber and a beam that supports the dielectric member. The plasma processing method is characterized in that the microwaves are transmitted through the dielectric member supported at the beam fixed onto the processing chamber from the outside of the processing chamber and that the subject is processed with plasma generated by raising to plasma a gas with the transmitted microwaves.

The beam may be fixed onto the processing chamber from the outside of the processing chamber via a plurality of screws that pass through a plurality of through holes formed at the processing chamber and interlock with the beam so that the microwaves are transmitted through the dielectric member supported at the beam.

In the processing apparatus, the beam screwed onto a top plate from the outside of the processing chamber. This means that the heads of the screws are not exposed at a surface that comes in contact with the plasma inside the processing chamber. Since the surface that comes in contact with the plasma inside the processing chamber is smoothed and flattened, substantially devoid of recesses or projections, concentration of electrical field energy around projected portions or entry of plasma at recessed portions which would induce an abnormal discharge can be inhibited. The structure thus makes it possible to generate uniform plasma in a stable manner without inducing excessive dissociation of the gas. As a result, the substrate can be processed with plasma in desirable conditions.

It is to be noted that the subject to be processed may be plasma-processed by using a microwave plasma processing apparatus with the plurality of screws inserted at the plurality of through holes formed at a processing chamber at intervals equal to or less than λ g/4 and the plurality of screws, too, set at intervals equal to or less than λ g/4.

As described above, the present invention provides a microwave plasma processing apparatus with surfaces within the processing chamber that come in contact with the plasma smoothed and flattened so as to minimize electrical field concentrations, a method for manufacturing the microwave plasma processing apparatus and a plasma processing method.

### BRIEF DESCRIPTION OF THE DRAWINGS

FIG. 1 is a longitudinal sectional view of the microwave plasma processing apparatus achieved in an embodiment of the present invention;

FIG. 2 shows the ceiling surface of the processing chamber with the beam screwed on from below in the embodiment;

FIG. 3 shows the beam screwed on from below in the embodiment;

FIG. 4 shows the ceiling surface of the processing chamber with the beam screwed on from above in the embodiment;

FIG. 5 shows the beam screwed on from above in the embodiment;

FIG. 6 shows the power dependency of the fixed electrical charge density observed in films formed in processing chambers with beam screwed on from above/below in the embodiment;

FIG. 7 shows the SiH4/O2 pressure-ratio dependency of the fixed electrical charge density observed in films formed in processing chambers with beam screwed on from above/below in the embodiment;

FIG. 8 shows the SiH4 pressure-ratio dependency of the fixed electrical charge density observed in films formed in processing chambers with beam screwed on from above/below in the embodiment; and

FIG. 9 shows the O2 pressure-ratio dependency of the fixed electrical charge density observed in films formed in processing chambers with beam screwed on from above/below in the embodiment.

### DETAILED DESCRIPTION OF THE EMBODIMENT

The following is a detailed explanation of the microwave plasma processing apparatus achieved in an embodiment of the present invention given in reference to the attached drawings. It is to be noted that in the following explanation and the attached drawings, the same reference numerals are assigned to components having identical structural features and functions to preclude the necessity for a repeated explanation thereof. In addition, the description in the specification is provided by assuming that 1 mTorr is equal to (10⁻³×101325/760) Pa and that 1 sccm is equal to (10^{-6′}/60) m³/sec.

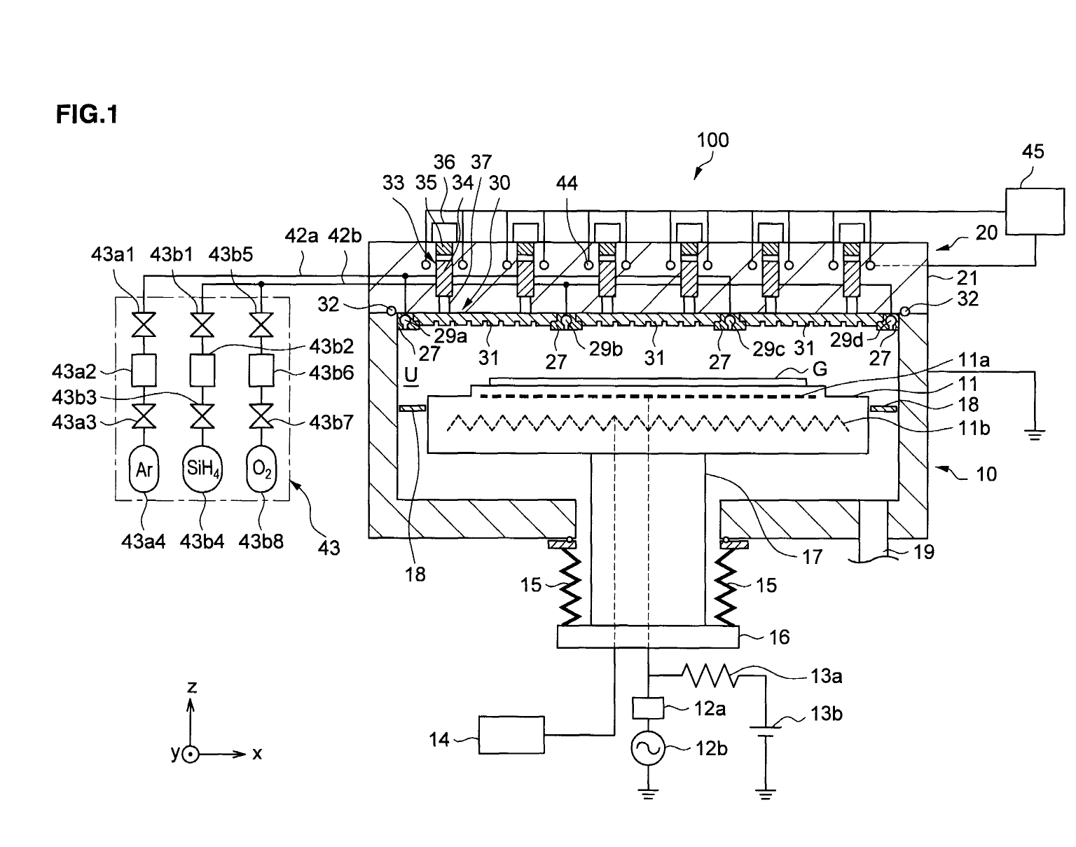

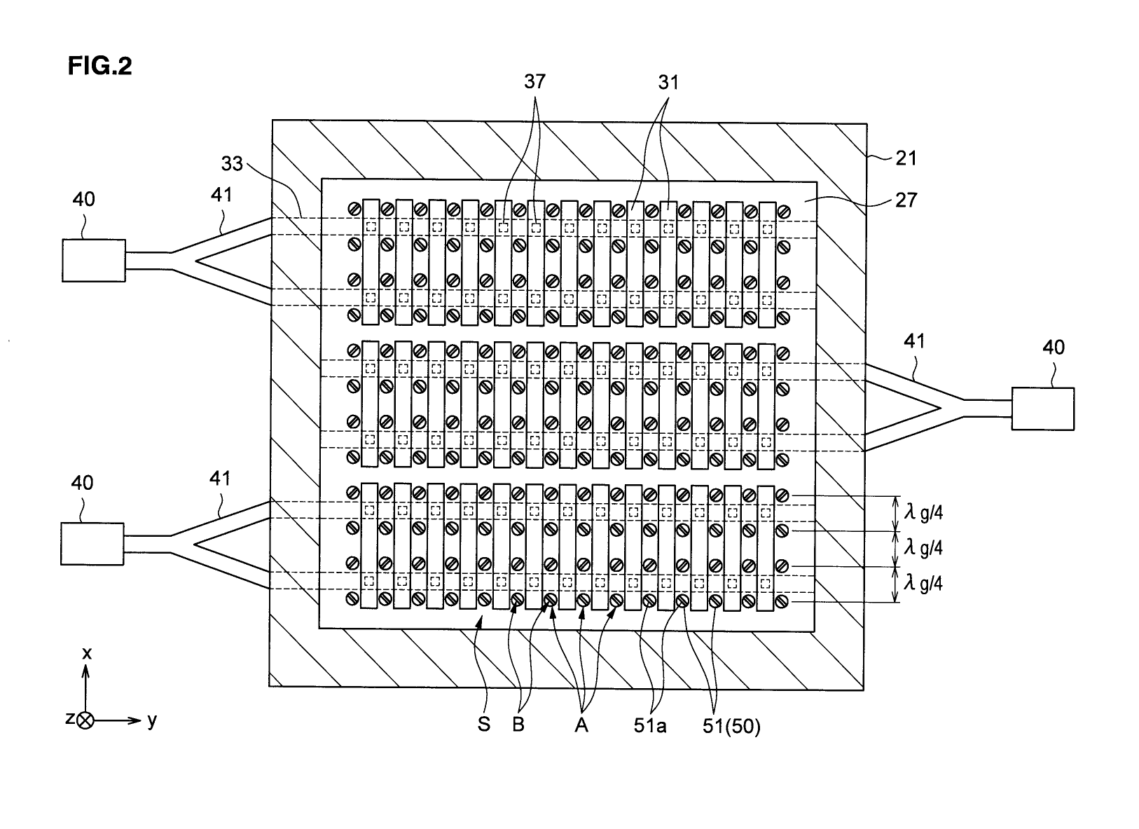

First, in reference to FIG. 1 presenting a sectional view of the microwave plasma processing apparatus achieved in the embodiment of the present invention, taken along the longitudinal direction (the direction perpendicular to the y-axis), and FIG. 2 presenting a view of the ceiling of the processing chamber, the structure adopted in the microwave processing apparatus is explained. It is to be noted that the following explanation focuses on a gate oxide film forming process executed in the microwave plasma processing apparatus achieved in the embodiment.

### (Structure Adopted in the Microwave Plasma Processing Apparatus)

A microwave plasma processing apparatus 100 includes a processing container 10 and a lid 20. The processing container 10 assumes a solid-bottomed cubic shape with an open top. The processing container 10 and the lid 20 are sealed together via an O-ring 32 disposed between the external circumference at the bottom surface of the lid 20 and the external circumference of the top surface of the processing container 10, thereby forming a processing chamber U where plasma processing is executed. The processing container 10 and the lid 20, which may be constituted of a metal such as aluminum, are electrically grounded.

Inside the processing container 10, a susceptor 11 (stage) on which a glass substrate (hereafter referred to as a “substrate”) G is placed is disposed. Inside the susceptor 11 constituted of, for instance, aluminum nitride, a power supply unit 11a and a heater 11b are installed.

A high-frequency power source 12b is connected to the power supply unit 11a via a matcher 12a (e.g., a capacitor). In addition, a high-voltage DC power source 13b is connected to the power supply unit 11a via a coil 13a. The matcher 12a, the high-frequency power source 12b, the coil 13a and the high-voltage DC power source 13b are all disposed outside the processing container 10. The high-frequency power source 12b and the high-voltage DC power source 13b are grounded.

The power supply unit 11a applies a predetermined level of bias voltage into the processing container 10 by using high-frequency power output from the high-frequency power source 12b. In addition, the power supply unit 11a electrostatically attracts and holds the substrate G with a DC voltage output from the high-voltage DC power source 13b.

An AC power source 14 disposed outside the processing container 10 is connected to the heater 11b, and the heater 11b thus maintains the temperature of the substrate G at a predetermined level by using an AC voltage output from the AC power source 14.

A cylindrical opening is formed at the bottom surface of the processing container 10, with one end of a bellows 15 attached to the outer circumferential edge of the opening on the bottom surface. The other end of the bellows 15 is locked to an elevator plate 16. The opening at the bottom surface of the processing container 10 is thus sealed with the bellows 15 and the elevator plate 16.

The susceptor 11, supported at a cylindrical member 17 disposed on the elevator plate 16, moves up and down as one with the elevator plate 16 and the cylindrical member 17, so as to adjust the height of the susceptor 11 at a position optimal for a specific processing operation. In addition, a baffle plate 18 is disposed around the susceptor 11 in order to control the gas flow in the processing chamber U in the optimal state.

A vacuum pump (not shown) disposed outside the processing container 10 is present near the bottom of the processing container 10. As the gas is exhausted with the vacuum pump from the processing container 10 via a gas exhaust pipe 19, the pressure inside the processing chamber U is lowered until a desired degree of vacuum is achieved.

At the lid 20, a lid main body 21 (top plate), six rectangular waveguides 33, a slot antenna 30 and a dielectric member (constituted with a plurality of dielectric parts 31) are disposed.

The six rectangular waveguides 33 have a rectangular section and are disposed parallel to one another inside the lid main body 21. The space inside each waveguide is filled with a dielectric material 34 such as a fluororesin (e.g., Teflon™), alumina (Al2O3) or quartz. Thus, the guide wavelength λ g1 within each rectangular waveguide 33 is controlled as indicated in expression; λ g1=λ c/(ε1)^{1/2}. λ c and ε1 in the expression respectively represent the wavelength in free space and the dielectic constant of the dielectric material 34.

The rectangular waveguides 33 each have an open top through which a movable portion 35 is allowed to move up/down freely. The movable portion 35 is constituted of a nonmagnetic, electrically conductive material such as aluminum.

Outside the lid 20, an elevator mechanism 36 is disposed at the upper surface of each movable portion 35 so as to move the movable portion 35 up/down. This structure allows the movable portion 35 to move up to a point level with the upper surface of the dielectric material 34 so as to freely adjust the height of the rectangular waveguide 33.

The slot antenna 30, located on the bottom side of the lid 20, is formed as an integrated part of the lid main body 21. The slot antenna 30 is constituted of a nonmagnetic metal such as aluminum. Thirteen slots 37 (openings) are formed in series, as shown in FIG. 2, at the slot antenna under the bottom surface of each rectangular waveguide 33. The space inside each slot 37 is filled with a dielectric material constituted of a fluororesin, alumina (Al2O3) or quartz, and the dielectric member enables control of the guide wavelength λ g₂ inside each slot 37, as indicated in expression: λ g₂=λ c/(ε₂)^{1/2}. λ c and ε₂ in the expression respectively represent the wavelength in free space and the dielectric constant of the dielectric material inside the slot 37. The area where the outer circumferential portion of each slot 37 and the corresponding dielectric part at the lower surface of the slot 37 come into contact with each other is sealed with an O-ring 52 so as to sustain the inner space in the processing chamber U in a sealed state.

The dielectric member is constituted with a plurality of dielectric parts 31. The dielectric parts 31 each assuming the shape of a tile, are disposed over three rows with 13 dielectric parts 31 set in each row so that each row of dielectric parts ranges over two rectangular waveguides 33 connected to a common microwave generator 40 via a Y branch pipe 41.

Each dielectric part 31 is installed so as to range over two slots with y coordinates equal to each other among the 26 (13 slots×2 rows) slots 37 formed under the two adjacent rectangular waveguides 33 (i.e., the two rectangular waveguides 33 connected to a common microwave generator 40). The structure described above includes a total of 39 (13×3 rows) dielectric parts 31 mounted at the bottom surface of the slot antenna 30.

The dielectric parts 31 are constituted of a dielectric material such as quartz glass, AlN, Al2O3, sapphire, SiN or a ceramic. As shown in FIG. 1, indentations and projections are formed at the surfaces of the dielectric parts 31 facing opposite the substrate G, as shown in FIG. 1. The presence of at least either indentations or projections formed at the surfaces of the dielectric parts 31 increases the loss of electrical field energy as surface waves are propagated over the surface of the dielectric part 31 and thus, the extent of surface wave propagation is minimized. This, in turn, inhibits the occurrence of a standing wave, thereby assuring generation of uniform plasma.

It is to be noted that any number of slots 37 may be formed under each rectangular waveguide 33. Twelve slots 37, for instance, may be formed under each rectangular waveguide 33 and a total of 36 (12×3 rows) dielectric parts 31 may be disposed at the bottom surface of the slot antenna 30, instead. In addition, the quantity of slots 37 present at the top surface of each dielectric part 31 does not need to be two, and there may be a single slot 37 or three or more slots 37 present at the top surface of each dielectric part 31.

At the lower surface of the slot antenna 30, a beam 27 formed in a lattice structure are disposed as shown in FIG. 2. The beam 27 supports the individual dielectric parts 31 over their peripheral edges. The beam 27 constituted of a nonmagnetic, electrically conductive material such as aluminum (Al), copper (Cu) or stainless steel (SuS) will have undergone a surface treatment such as Cr—Ni—Al diffusion processing to achieve better anti-corrosion performance. It is to be noted that the beam 27, which is fixed onto the ceiling surface of the processing chamber U with screws, should be preferably constituted of stainless steel with superior strength, so as to assure the required level of mechanical strength. The specific method that may be adopted when fixing the beam 27 is to be described in detail later.

A gas supply source 43 in FIG. 1 is constituted with a plurality of valves (valves 43a1, 43a3, 43b1, 43b3, 43b5 and 43b7), a plurality of mass flow controllers (mass flow controllers 43a2, 43b2 and 43b6), an argon gas supply source 43a4, a silane gas supply source 43b4 and an oxygen gas supply source 43b8.

Argon gas, silane gas and oxygen gas, each achieving a desired level of density, are individually supplied into the processing container 10 from the gas supply source 43 by individually controlling the open/closed states of the valves 43a1, 43a3, 43b1, 43b3, 43b5 and 43b7 and the degrees of openness of the various mass flow controllers 43a2, 43b2 and 43b6.

Gas supply pipes 29a˜29d pass through the beam 27. The argon gas supply source 43a4 is connected via a first flow passage 42a to the gas supply pipes 29a and 29c. The silane gas supply source 43b4 and the oxygen gas supply source 43b8 are connected via a second flow passage 42b to the gas supply pipes 29b and 29d.

Cooling water pipes 44 in FIG. 1 are connected with a cooling water supply source 45 installed outside the microwave plasma processing apparatus 100 and as cooling water supplied from the cooling water supply source 45 circulates through the cooling water pipes 44 and returns to the cooling water supply source 45, the temperature at the lid main body 21 is maintained at a desired level.

In the plasma processing apparatus adopting the structure described above, 2.45 GHz×3 microwaves, for instance, having passed through the individual slots 37, are transmitted through the dielectric parts 31 and enter the processing chamber U. In addition, a desired type of gas is supplied from the gas supply source 43 into the processing chamber U. The supplied gas is then raised to plasma with the electrical field energy of the microwaves inside the processing container with the pressure therein sustained at a desired degree of vacuum and a gate oxide film is formed on the substrate G with this plasma.

### (Method for Fixing the Beam)

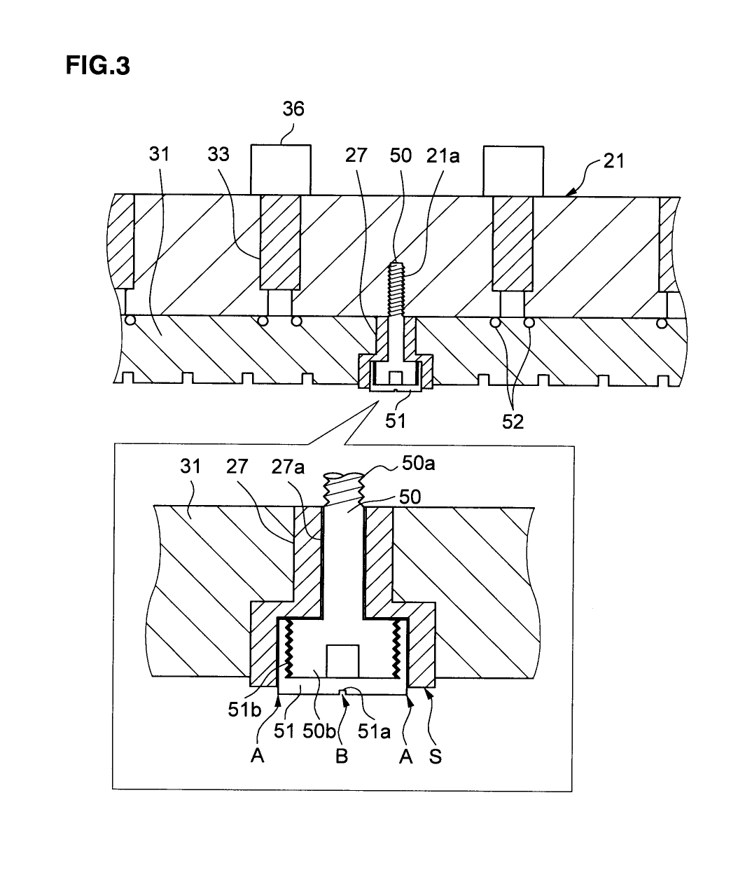

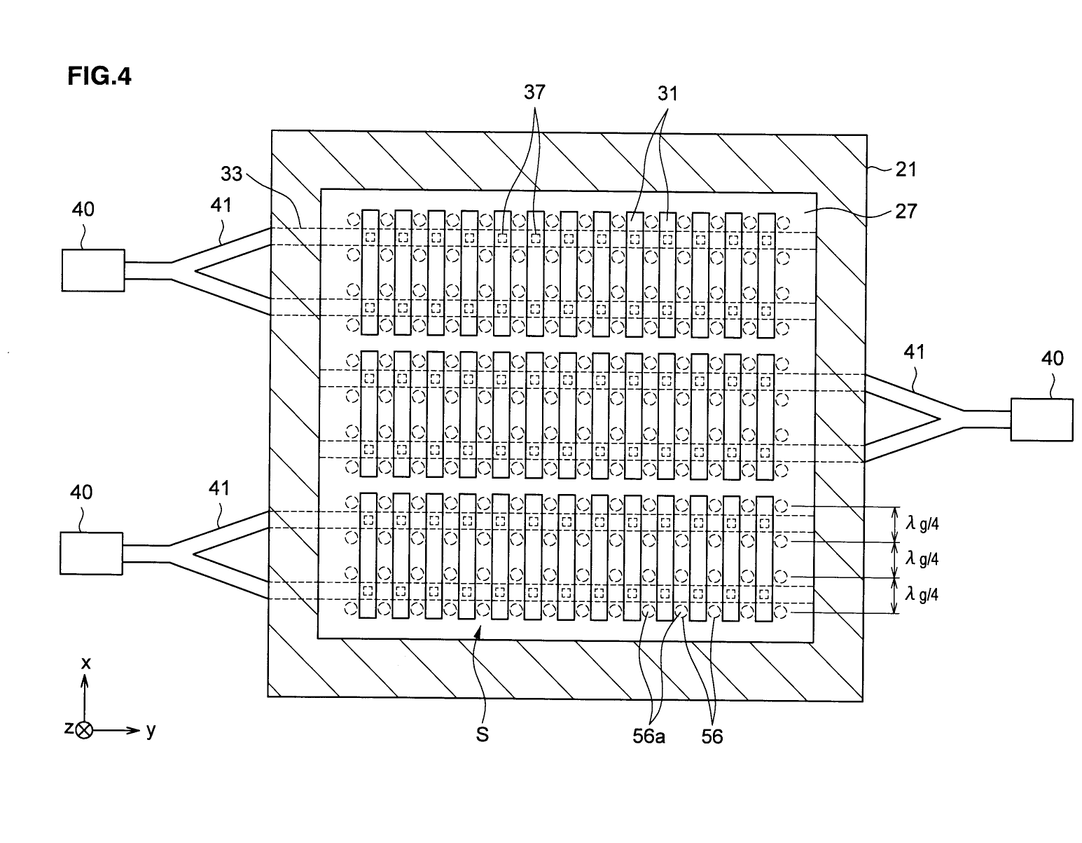

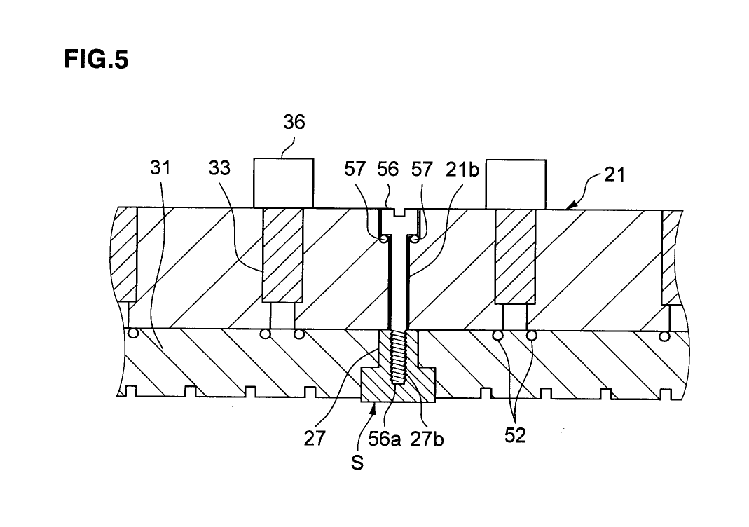

Next, the method for fixing the beam 27 proposed by the inventor is explained in reference to FIGS. 2˜5. FIGS. 2 and 3 show a ceiling surface onto which the beam 27 is screwed from below and the bottom screwing method adopted at the ceiling, whereas FIGS. 4 and 5 shows a ceiling surface onto which the beam 27 is screwed from above and the top screwing method adopted at the ceiling.

### (Bottom Screwing)

A structure with the beam 27 screwed on from below (i.e., from the inside of the processing chamber U) as shown in FIG. 3 is first explained. As shown in the enlargement presented in FIG. 3, through holes 27a at which male screws 50 are to be inserted are present over the surface of the beam 27 on one side with a pitch equal to or less than λ g/4, as shown in FIG. 2 (with a λ g/4 pitch in this example). λ g represents the wavelength within the waveguide.

When fixing the beam 27 from the inside of the processing chamber U via screws, the upper surfaces of the dielectric parts 31 supported by the beam 27 over their peripheral edges are placed in surface contact with the lower surface of the top plate (lid main body 21) constituting the ceiling of the processing chamber U. Then, the screws 50 are inserted from the inside of the processing chamber U through the through holes 27a formed at the beam 27 and threaded portions 50a (see the enlarged view in FIG. 3) of the inserted screws 50 are made to interlock with threaded screw holes 21a formed in advance at the top plate (lid main body 21) by using a hexagonal wrench. The beam 27 thus becomes locked onto the top plate from the inside of the processing chamber U. After fixing the beam 27 and the top plate onto each other from the inside of the processing chamber U via the plurality of screws 50 as described above, a driver is inserted at a recessed portion 51a formed on the outside of each aluminum cap 51 and the aluminum cap 51 is screwed into the area between the beam 27 and a head portion 50b of the screw 50 by interlocking the head portion 50b of the screw 50 with a screw hole 51b at the aluminum cap 51. As a result, the aluminum cap 51 is set over the head portion 50b of the screw 50.

When the beam 27 is fixed to the top plate with the screws 50 from the inside of the processing chamber U as described above, the aluminum caps 51 projecting out beyond surface S of the beam 27 (the beam surface that comes in contact with the plasma) are exposed inside the processing chamber U. Numerous aluminum caps 51 are arrayed on the ceiling surface of the processing chamber U with a pitch of substantially λ g/4, as shown in FIG. 2. When circular projections A at the surface S of the beam 27 are arrayed on the ceiling surface of the processing chamber U with an interval substantially equal to λ g/4, as described above, the electrical field energy of the microwaves having been transmitted through the dielectric parts 31 and supplied into the processing chamber U concentrates around the projections A arrayed on the ceiling surface.

As explained earlier, the recessed portion 51a (see the enlargement in FIG. 3), at which the driver is inserted, is formed at each aluminum cap 51. Thus, recessed portions indicated as B are present at the surface S of the beam 27 with an interval substantially equal to λ g/4, as shown in FIGS. 2 and 3. The plasma generated under the dielectric parts 31, which tends to readily enter narrow spaces, enters inside these recessed portions B, inducing an abnormal discharge inside the recessed portions B.

Ultimately, the presence of the recesses and projections at the aluminum caps 51 exposed at the surface S of the beam 27 will cause concentration of the electrical field energy in the microwaves and abnormal discharges near the lower surfaces of the dielectric parts 31, as a result, will induce excessive dissociation of the SiH4 gas, lower the quality of the film being formed and cause ununiformity in the film being formed due to the unevenness of the plasma being generated.

### (Top Screwing)

Accordingly, the inventor devised an improvement for smoothing and flattening the surface S of the beam 27 and conceived a method for screwing the beam 27 onto the top plate from the outside of the processing chamber U, as shown in FIG. 5. This method can be implemented in conjunction with the lid main body 21 (top plate) having formed therein numerous through holes 21b through which screws 56 are to pass set with a pitch equal to or less than λ g/4 (with a pitch of λ g/4 in this example).

When fixing the beam 27 from the inside of the processing chamber U, the upper surfaces of the dielectric parts 31 supported by the beam 27 over their peripheral edges are placed in surface contact with the lower surface of the top plate (lid main body 21) constituting the ceiling of the processing chamber U. Then, the screws 56 are inserted from the outside of the processing chamber U through the through holes 21a formed at the top plate (lid main body 21) and the threaded portions 56a of the inserted screws 56 are made to interlock with threaded screw holes 27b formed at the beam 27 by using a hexagonal wrench. The beam 27 thus becomes locked onto the top plate from the outside of the processing chamber U. After fixing the beam 27 onto the top plate via the plurality of screws 56 from the outside of the processing chamber U as described above, the gap between the screw 56 and the corresponding through hole 21b at which the screw 56 is inserted is sealed with an O-ring 57.

When the beam 27 is fixed onto the top plate with the screws 56 from the outside of the processing chamber U as described above, as shown in FIG. 4, the numerous screws 56 present at a pitch substantially equal to λ g/4 at the ceiling surface of the processing chamber U are not exposed over the ceiling surface. Namely, the surface S of the beam 27 is a smooth, flat surface devoid of recesses or projections. As a result, excessive dissociation of the gas due to electrical field energy concentration and abnormal electrical discharge does not occur and a good quality film can be formed with uniform and stable plasma.

It is crucial to set the numerous screws 56 (and the screws 50 used for bottom screwing) with a pitch equal to or less than λ g/4 when fixing the beam 27 onto the top plate for the following reason. Generally speaking, waves with a wavelength λ cannot advance through gaps present over an interval equal to or less than λ g/4. This means that the gaps present over an interval equal to or less than λ g/4 constitute barriers for microwaves having been propagated through the rectangular waveguides 33 and transmitted through the dielectric parts 31 and thus, the microwaves cannot advance through the gaps. Since the microwaves are thus not allowed to leak through the gaps formed over the areas where the screws 56 or 50 are fixed, a microwave power loss does not occur.

In addition, it is desirable that the screws 50 and the screws 56 be constituted of a non-magnetic electrically conductive material as is the beam 27. By assuring a high level of electrical conductivity through the beam 27 and the screws, magnetization of the screws by the electromagnetic field energy in the microwaves is inhibited. As a result, since there is no magnetism imparted from the beam 27 and the screws to affect the plasma, the uniformity of plasma is achieved. It is to be noted that the plurality of screws 56 constitute the fixing means for fixing the beam 27 onto the top plate (lid main body 21) from the outside of the processing chamber U.

### (Test Results)

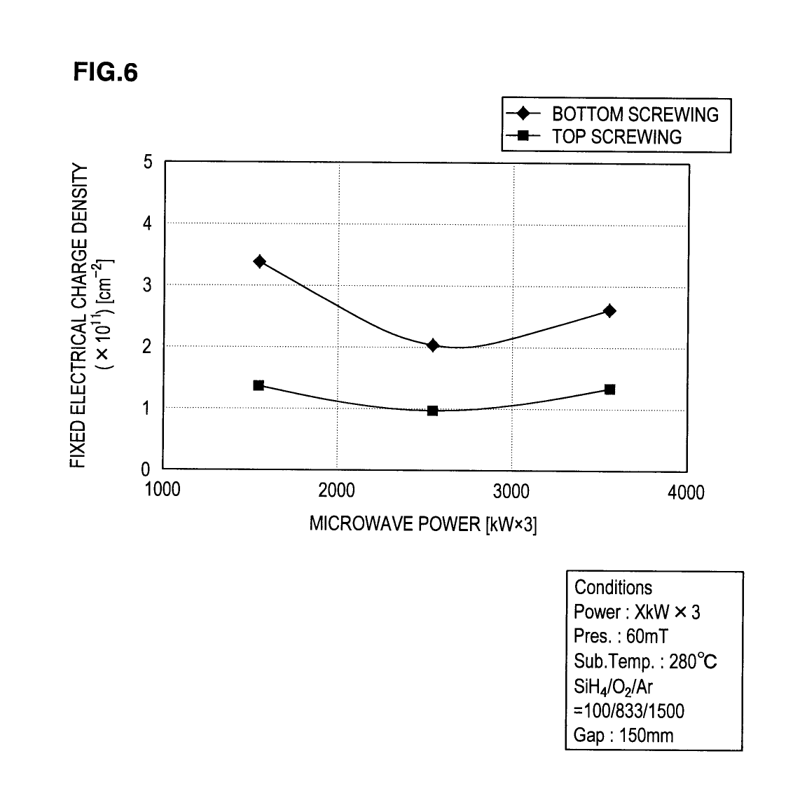

The inventor actually executed gate oxide film formation processing by using a microwave plasma processing apparatus with the beam 27 fixed from below (bottom screwing) and a microwave plasma processing apparatus with the beam 27 fixed from above (top screwing). The results of these tests are presented in FIGS. 6 through 9.

During the tests, the inventor measured changes occurring in the fixed electrical charge density in the microwave plasma processing apparatus with the beam screwed on from below and the microwave plasma processing apparatus with the beam screwed on from above under the following processing conditions. The fixed electrical charge density can be used as an indicator when evaluating the quality and the uniformity of a gate oxide film. A low fixed electrical charge density level indicates that the film quality is high and a lesser extent of change in the fixed electrical charge density relative to changes in the individual variables indicates that the film is formed with better uniformity.

### (Microwave Power Dependency)

The following is the observations made based upon the test results. First, changes in the fixed electrical charge density occurring as the microwave power is altered are explained in reference to FIG. 6. The tests were conducted under the following processing conditions; the microwave power set at x (the horizontal axis in FIG. 6) kW×3 (three microwave generators 40 were used), the pressure (Pres.) set at 60 mTorr, the stage temperature (Sub.Temp) set at 280° C., the gas flow rates of the various gas constituents set at SiH4/O2/Ar=100/833/1500 sccm and the distance between the dielectric member (dielectric parts 31) and the substrate (susceptor 11) set at 150 mm.

During the tests, the inventor measured the fixed electrical charge density levels of gate oxide films formed as the microwave power was switched to 1.55 kW, 2.55 kW and 3.55 kW. The results indicate that the fixed electrical charge density measured in the microwave plasma processing apparatus with the beam screwed on from above was clearly lower, i.e., approximately ½ of the fixed electrical charge density measured in the microwave plasma processing apparatus with the beam screwed on from below. These findings led the inventor to a conclusion that while excessive dissociation of SiH4 tends to occur readily to result in the formation of a gate oxide film with an inferior quality in the microwave plasma processing apparatus with the beam screwed on from below, which leaves the screws exposed at the ceiling surface of the processing chamber U due to concentration of electrical field energy around the projected portions of the exposed screws and abnormal discharge occurring in the recessed portions of the exposed screws, such electrical field energy concentration and abnormal discharge does not occur and thus excessive dissociation of SiH4 does not occur readily in the microwave plasma processing apparatus with the beam screwed on from above with no screws exposed at the ceiling surface of the processing chamber U, thereby noticeably improving the quality of the gate oxide film.

In addition, as the microwave power was altered, the fixed electrical charge density in the microwave plasma processing apparatus with the beam thereof screwed on from above did not fluctuate as much as the fixed electrical charge density in the microwave plasma processing apparatus with the beam thereof screwed on from below. These findings led the inventor to the logical conclusion that while the plasma generated in the microwave plasma processing apparatus with the beam screwed on from below became inconsistent and unstable due to concentration of electrical field energy occurring around the projected portions and the recessed portions of the exposed screws and at the edges of the screw contact portions and due to abnormal discharge occurring in the recessed portions of the exposed screws and in the gaps at the screw contact areas, such phenomena did not manifest in the microwave plasma processing apparatus with the beam screwed on from above with no recesses or projections formed at the ceiling surface of the processing chamber where uniform plasma could be generated in a stable manner. This allowed the inventor to draw a further conclusion that even when a certain extent of fluctuation in the power of the microwaves transmitted into the processing container occurs in the microwave plasma processing apparatus with the beam thereof screwed on from above, uniform plasma can still be generated in a stable manner and, as a result, a uniform gate oxide film can be formed.

These conclusions were substantiated by observations made during the tests that while localized light emission was observed in the plasma generated in the microwave plasma processing apparatus with the beam screwed on from below, no such localized light emission occurred in the plasma generated in the microwave plasma processing apparatus with the beam screwed on from above.

### (SiH4/O2 Pressure-Ratio Dependency)

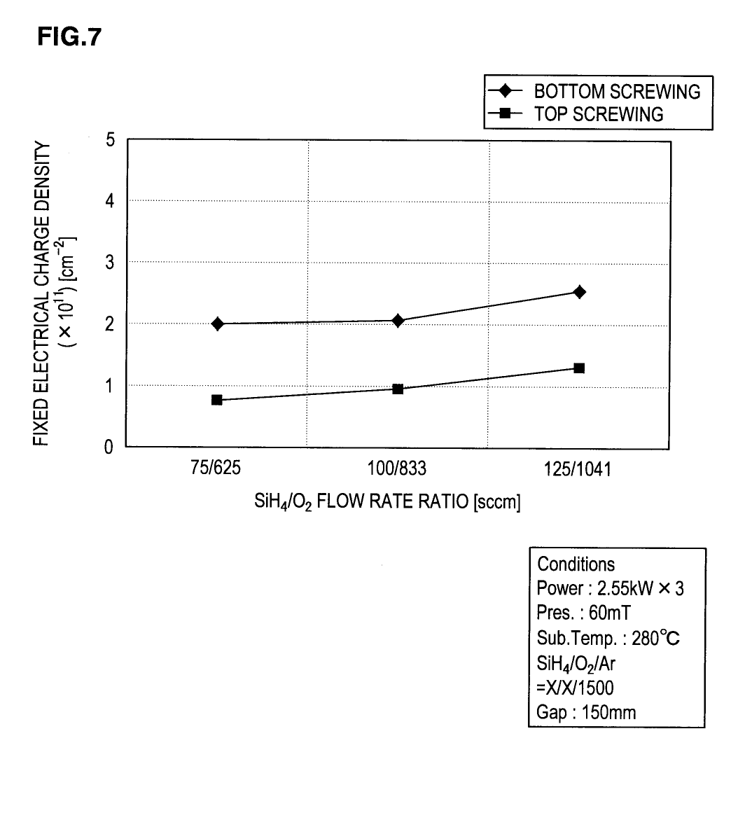

Next, the test results obtained by altering the SiH4/O2 flow rate ratio are explained in reference to FIG. 7. The tests were conducted under the following processing conditions; the microwave power set at 2.55 kW×3 (three microwave generators 40 were used), the pressure (Pres.) set at 60 mTorr, the stage temperature (Sub.Temp) set at 280° C., the gas flow rates of the various gas constituents set at SiH4/O2/Ar=x/x(horizontal axis in FIG. 7)/1500 sccm and the distance between the dielectric member (dielectric parts 31) and the substrate (susceptor 11) set at 150 mm.

During the tests, the inventor measured the fixed electrical charge density levels of gate oxide films formed as the SiH4/O2 flow rate ratio was switched to 75/625 sccm, 100/833 sccm and 125/1041 sccm. The results indicate that the fixed electrical charge density measured in the microwave plasma processing apparatus with the beam screwed on from above was clearly lower, i.e., approximately ½ of the fixed electrical charge density measured in the microwave plasma processing apparatus with the beam screwed on from below. The inventor was thus able to verify that similar results were obtained through the SiH4/O2 pressure-ratio dependency tests to those obtained through the microwave power dependency tests.

### (SiH4 Pressure Ratio Dependency)

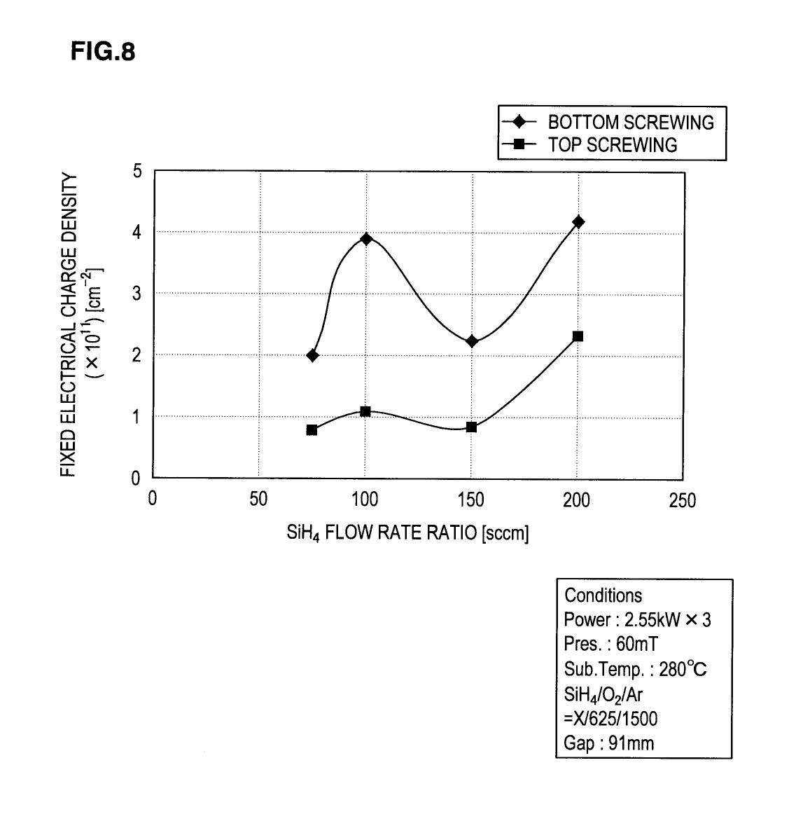

Next, the test results obtained by altering the SiH4 flow rate ratio are explained in reference to FIG. 8. The tests were conducted under the following processing conditions; the microwave power set at 2.55 kW×3 (three microwave generators 40 were used), the pressure (Pres.) set at 60 mTorr, the stage temperature (Sub.Temp) set at 280° C., the gas flow rates of the various gas constituents set at SiH4/O2/Ar=x/(horizontal axis in FIG. 8)/625/1500 sccm and the distance between the dielectric member (dielectric parts 31) and the substrate (susceptor 11) set at 91 mm.

During the tests, the inventor measured the fixed electrical charge density levels of gate oxide films formed as the SiH4 flow rate ratio was switched to 75 sccm, 100 sccm, 150 sccm and 200 sccm. The results indicate that the fixed electrical charge density measured in the microwave plasma processing apparatus with the beam screwed on from above was clearly lower, i.e., approximately ½ of the fixed electrical charge density measured in the microwave plasma processing apparatus with the beam screwed on from below.

In addition, the fixed electrical charge density in the microwave plasma processing apparatus with the beam screwed on from above fluctuated markedly less than the fixed electrical charge density in the microwave plasma processing apparatus with the beam screwed on from below as the SiH4 flow rate ratio was altered. The inventor was thus able to verify that similar results were obtained through the SiH4 pressure-ratio dependency tests to those obtained through the microwave power dependency tests.

### (O2 Pressure Ratio Dependency)

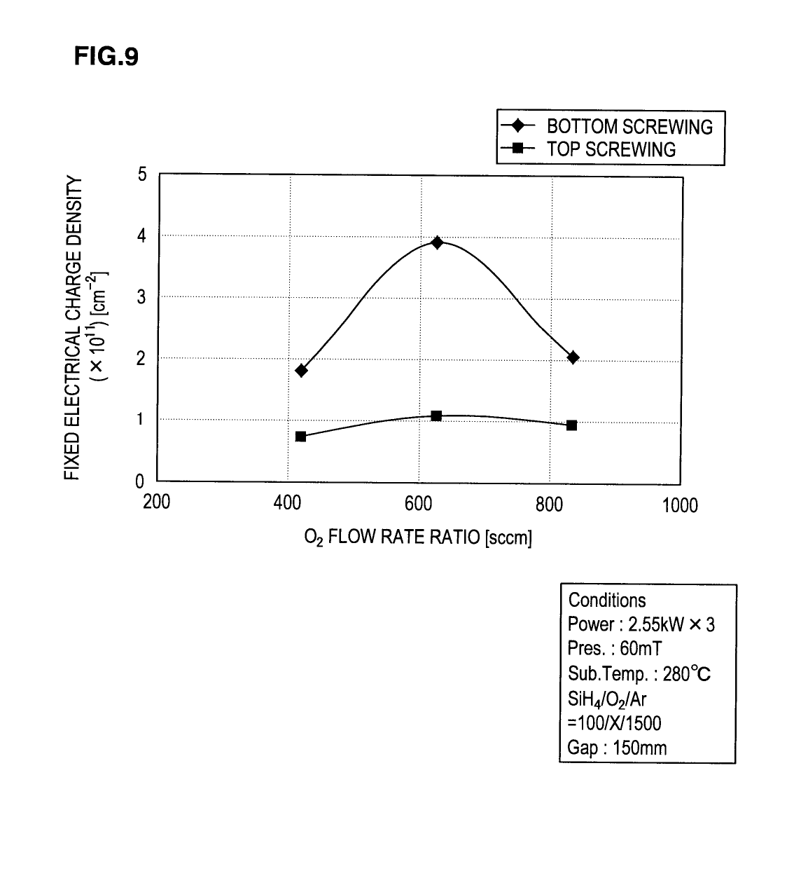

Lastly, the test results obtained by altering the O2 flow rate ratio are explained in reference to FIG. 9. The tests were conducted under the following processing conditions; the microwave power set at 2.55 kW×3 (three microwave generators 40 where used), the pressure (Pres.) set at 60 mTorr, the stage temperature (Sub.Temp) set at 280° C., the gas flow rates of the various gas constituents set at SiH4/O2/Ar=100/×(horizontal axis in FIG. 9)/1500 sccm and the distance between the dielectric member (dielectric parts 31) and the substrate (susceptor 11) set at 150 mm.

During the tests, the inventor measured the fixed electrical charge density levels of gate oxide films formed as the O2 flow rate ratio was switched to 417 sccm, 625 sccm and 833 sccm. The results indicate that the fixed electrical charge density measured in the microwave plasma processing apparatus with the beam screwed on from above was clearly lower, i.e., approximately ½ of the fixed electrical charge density measured in the microwave plasma processing apparatus with the beam screwed on from below.

In addition, the fixed electrical charge density in the microwave plasma processing apparatus with the beam screwed on from above fluctuated markedly less than the fixed electrical charge density in the microwave plasma processing apparatus with the beam screwed on from below as the O2 flow rate ratio was altered. The inventor was thus able to verify that similar results were obtained through the O2 pressure-ratio dependency tests to those obtained through the microwave power dependency tests.

These test results allow the inventor to prove that while the microwave plasma processing apparatus with an improvement achieved by securing the beam from above adopts a simple structure, it is extremely effective for stable generation of uniform plasma.

It is to be noted that the glass substrate may measure 720 mm×720 mm or more and the present embodiment may be adopted in conjunction with glass substrates measuring 720 mm×720 mm in the G3 substrate size (the inner diameter of the chamber: 400 mm×500 mm), 730×920 in the G4.5 substrate size (the inner diameter of the chamber: 1000 mm×1190 mm) and 1100 mm×1300 mm in the G5 substrate size (the inner diameter of the chamber: 1470 mm×1590 mm), for instance. In addition, while the power output from the microwave generators may be within the range of 1˜8 W/cm², it is more desirable to set the power output within a range of 2.2˜3 W/cm².

The operations of the individual units, executed in the embodiment as described above, are correlated and thus, they may be regarded as a series of operations by bearing in mind how they relate to one another. By considering them as a sequence of operations, the embodiment of the plasma processing apparatus can be remodeled as an embodiment of a plasma processing method to be adopted when executing plasma processing by using microwaves.

While the invention has been particularly shown and described with respect to a preferred embodiment thereof by referring to the attached drawings, the present invention is not limited to these examples and it will be understood by those skilled in the art that various changes in form and detail may be made therein without departing from the spirit, scope and teaching of the invention.

For instance, the plasma processing apparatus according to the present invention may be a microwave plasma processing apparatus with a plurality of dielectric members (i.e., dielectric parts 31) each assuming the shape of a tile or it may be a microwave plasma processing apparatus that includes a single dielectric member with a large area that is not divided into tile-like parts.

In addition, while an explanation is given above in reference to the embodiment on an example in which the present invention is adopted in a microwave plasma processing apparatus that processes large glass substrates during large display device production, the present invention may also be adopted in a microwave plasma processing apparatus utilized in semiconductor device production.

Furthermore, the plasma processing executed in the plasma processing apparatus according to the present invention does not need to be film formation processing, and the plasma processing apparatus according to the present invention may execute all types of plasma processing including diffusion processing, etching and ashing.

What is claimed is;

1. A microwave plasma processing apparatus that processes a subject with plasma generated by raising a gas to plasma with microwaves, comprising;
a processing chamber;
a dielectric member that allows the microwaves to be transmitted into the processing chamber;
a beam that supports the dielectric member; and
a fixing means for fixing the beam to the processing chamber from outside the processing chamber.

2. The microwave plasma processing apparatus according to claim 1, wherein:
a plurality of through holes are present at the processing chamber; and
the fixing means includes a plurality of screws which pass through the plurality of through holes at the processing chamber from outside the processing chamber and interlock with the beam.

3. The microwave plasma processing apparatus according to claim 2, wherein:
the plurality of screws are set over an interval equal to or less than λ g/4.

4. The microwave plasma processing apparatus according to claim 2, further comprising:
O-rings that seal a gap formed between each of the plurality of screws and each of the plurality of through holes at which the each screw is inserted.

5. The microwave plasma processing apparatus according to claim 1, wherein:
the beam is constituted of a nonmagnetic, electrically conductive material.

6. The microwave plasma processing apparatus according to claim 2, wherein:
the plurality of screws are constituted of a nonmagnetic, electrically conductive material.

7. The microwave plasma processing apparatus according to claim 1, wherein:
the dielectric member is constituted with a plurality of dielectric parts; and
the beam is formed as a lattice structure in order to support the plurality of dielectric parts.

8. The microwave plasma processing apparatus according to claim 1, wherein:
a dimensions of the processing chamber is equal to or greater than 720 mm×720 mm.

9. The microwave plasma processing apparatus according to claim 1, wherein:
microwaves achieving a power level of 1˜8 W/cm² is supplied from a microwave generator into the processing chamber.

10. The microwave plasma processing apparatus according to claim 1, that generates plasma inside the processing chamber and processes the subject with the plasma generated after reducing the pressure inside the processing chamber until a desired degree of vacuum is achieved.

11. A method for manufacturing a microwave plasma processing apparatus that includes a processing chamber, a dielectic member that allows microwaves to be transmitted into the processing chamber and a beam that supports the dielectric member, and processes a subject with plasma generated by raising to plasma a gas with the microwaves transmitted through the dielectric member, comprising:
supporting the dielectric member at the beam;
fixing the beam to the processing chamber by inserting a plurality of screws through a plurality of through holes present at the processing chamber from outside the processing chamber; and
interlocking the screws with the beam.

12. A method for manufacturing a microwave plasma processing apparatus according to claim 11, wherein:
the plurality of screws are set with an interval equal to or less than λ g/4 by inserting the plurality of screws at the plurality of through holes present at the processing chamber over an interval equal to or less than λ g/4.

13. A plasma processing method for plasma-processing a subject to be processed with a microwave plasma processing apparatus that includes a processing chamber, a dielectric member that allows microwaves to be transmitted into the processing chamber and a beam that supports the dielectric member, comprising:
transmitting microwaves through the dielectric member supported by the beam fixed to the processing chamber from outside the processing chamber; and
processing the subject to be processed with plasma generated by raising to plasma a gas with the transmitted microwaves.

14. The plasma processing method according to claim 13, wherein:
the beam is fixed to the processing chamber by interlocking a plurality of screws inserted at a plurality of through holes present at the processing chamber from outside the processing chamber, and the microwaves are transmitted through the dielectric member supported at the beam.

15. The plasma processing method according to claim 13, wherein:
the plurality of screws are set with an interval equal to or less than λ g/4 by inserting the plurality of screws at the plurality of through holes present at the processing chamber over an interval equal to or less than λ g/4.
